(19) United States
(12) Patent Application Publication
(10) Pub. No.: US 2023/0263061 A1
(43) Pub. Date: Aug. 17, 2023

(54) METHOD FOR PRODUCING A THERMOELECTRIC MODULE, AND THERMOELECTRIC MODULE AS INTERFERENCE FIT ASSEMBLY

(71) Applicant: Fraunhofer-Gesellschaft zur Förderung der angewandten Forschung e.V., München (DE)

(72) Inventors: Olaf Schäfer-Welsen, Freiburg (DE); Uwe Vetter, Freiburg (DE); Marc Vergez, Freiburg (DE); Jan König, Freiburg (DE)

(73) Assignee: Fraunhofer-Gesellschaft zur Förderung der angewandten Forschung e.V., München (DE)

(21) Appl. No.: 18/014,203

(22) PCT Filed: Jun. 18, 2021
(86) PCT No.: PCT/EP2021/066635

§ 371 Date: Jan. 3, 2023

(30) Foreign Application Priority Data
Jul. 1, 2020 (EP) 20183520.4

(51) Int. Cl. H10N 10/17; H10N 10/01

(52) U.S. Cl. CPC H10N 10/17; H10N 10/01

(57) ABSTRACT

A method for producing a thermoelectric module (1) having an inner tube (2), and an outer tube (8), and at least two thermoelectric base elements (5), the method including providing the thermoelectric base elements (5) outside the inner tube (2) or inside the outer tube, and widening the inner tube (2) and/or shrinking the outer tube (8). At least one plastically or elastically deformable functional layer is applied between the inner tube (2) and the thermoelectric base elements (5) and/or between the thermoelectric base elements (5) and the outer tube (8) before the widening/shrinking, and the thermoelectric base elements (5) are operatively connected to the functional layer parallel to the inner tube (2), such that an interference fit assembly is produced by the widening of the inner tube (2) and/or the shrinkage of the outer tube (8).

### TECHNICAL FIELD

The invention relates to a method of producing a thermoelectric module, to a thermoelectric module and to a heat exchanger, to a cooling device and to a use thereof.

### BACKGROUND

One use of thermoelectric modules is as Peltier modules for cooling and in thermoelectric generators for the conversion of waste heat to power. Potentially utilizable waste heat arises in many areas of daily life, for example in transport, in the household or in industry. Thermoelectric generators can be used to convert the waste heat to electrical energy.

Thermoelectrics is based on the use of thermoelectric materials that exhibit the Seebeck effect. By means of these materials, it is possible to generate power even from small temperature differentials. The Seebeck effect gives rise to an electrical voltage in a circuit composed of two electrical conductors composed of thermoelectric material in the event of a temperature differential between the contact sites, as a result of thermal diffusion currents in the thermoelectric material. Typically, for this purpose, semiconductor materials are used, since these show a marked Seebeck effect and hence higher conversion efficacies are achievable.

What is crucial both in the implementation of the thermoelectric generators and in the case of cooling devices is integration of the thermoelectric module into the heat exchanger. The prior art discloses planar thermoelectric modules that are used, for example, with finned heat exchangers or plate fin heat exchangers, which are printed onto the planar thermoelectric modules. A disadvantage of plate fin heat exchangers is that they have a tendency to fouling and soot deposition on account of their small flow channels. They are virtually impossible to clean mechanically and require other cleaning methods, which makes them maintenance-intensive. Such heat exchangers are therefore often designed as disposable products. The long lifetime of thermoelectric modules and virtually maintenance-free operation cannot show their benefits in this combination.

The construction of thermoelectric generators is known from the prior art and typically comprises a hot side with a hot-side reservoir, one or more heat transferers, and a cold side with a cold-side reservoir.

The thermoelectric heat exchanger typically comprises fluid feeds and fluid drains to the hot side and cold side, and one or more thermoelectric modules.

The thermoelectric modules typically comprise heat transferers, and multiple thermoelectric base elements composed of electrically connected thermoelectric materials. The thermoelectric materials are typically electrically connected in series and thermally connected in parallel.

The prior art discloses welding and/or soldering thermoelectrically active elements onto tubes. DE 10 2010 061 247 B4 discloses a thermoelectric generator in which thermoelectric modules are produced in a fixed composite by means of soldering methods or laser welding methods. These production methods are complex and costly. A further disadvantage is that the thermoelectric generators thus produced are subject to severe mechanical stresses as a result of material expansion owing to the fluctuations in temperature. This leads to rapid wear.

### SUMMARY

It is therefore an object of the invention to propose a simple and inexpensive method of producing thermoelectric modules and a corresponding thermoelectric module, which are comparatively insensitive to thermal stresses.

This object is achieved by a production method and by a thermoelectric module and by a heat exchanger, a thermoelectric generator, a cooling device and a use thereof, all having one or more of the features disclosed herein.

Preferred configurations of the method of the invention and the thermoelectric module can be found below and in the claims.

The production method of the invention for production of a thermoelectric module from at least an inner tube and an outer tube and at least two thermoelectric base elements comprises, as is known per se, the following method steps:
A providing at least one inner tube,
B providing the outer tube,
C providing the thermoelectric base elements outside the inner tube and/or inside the outer tube, and
D widening the inner tube and/or shrinking the outer tube.

Essential features are that, in a method step C0 prior to method step D, at least one plastically or elastically deformable functional layer is applied between inner tube and thermoelectric base elements and/or between thermoelectric base elements and outer tube, and the thermoelectric base elements in method step C are incorporated with their longitudinal extent parallel to the longitudinal extent of the inner tube and operatively connected to the functional layer, such that the widening of the inner tube and/or shrinkage of the outer tube give rise to an interference fit assembly composed of at least inner tube, functional layer, thermoelectric base elements and outer tube.

The detailed sequence of method steps is nonlimiting. Both a construction beginning with the inner tube and one beginning with the outer tube are within the scope of the invention.

The invention is founded in the finding by the applicant that, through the use of a plastically and/or elastically deformable functional layer, it is possible to produce thermoelectric modules by means of an interference fit assembly purely in a force-fitting manner, i.e. without unreliable cohesive bonds.

“Without cohesive bonding” in the context of this description refers to the essential integrity of the components of the interference fit assembly, namely at least inner tube, functional layer, thermoelectric base elements and outer tube. This does not rule out cohesive bonds in the form of soldering sites for the contact connection of the thermoelectric base elements or for the contact connection or insulation of the semiconductor elements or the like.

The method of the invention for production of thermoelectric modules thus differs from previously known methods in essential aspects:

A plastically or elastically deformable functional layer is provided between the thermoelectric base elements, i.e. the thermoelectric materials that are connected via electrically conductive bridges, and the inner tube. Alternatively or additionally, a plastically or elastically deformable functional layer is provided between thermoelectric base elements and outer tube. As a result of the widening of the inner tube and/or shrinkage of the outer tube, inner tube, functional layers, thermoelectric base elements and outer tube are connected to one another by means of an interference fit assembly, i.e. by a force fit. These components are thus connected to one another in a partable manner. This results in the advantage that no unreliable cohesive bonds are used. Shear forces on account of different changes in axial length, typically caused by thermal expansion as a result of the temperature differences of the hot side and cold side of thermoelectric modules, are compensated for by the elastic or plastic interlayers. By virtue of the elastic and/or plastic properties, the functional layers are able to follow thermal or mechanical influences in a sustained or temporary manner in that, for example, they show flow characteristics or tolerate elastic deformation. This enables very flexible use of the thermoelectric base elements both with an external and an internal hot side of a heat exchanger.

It is further advantageous that materials having a significant change in length as well, for example shape-memory alloys as parts of the composite, would be usable, for example, as inner tube and/or outer tube.

Preference is given in each case to applying a plastically or elastically deformable functional layer between inner tube and thermoelectric base elements and between thermoelectric base elements and outer tube. However, it is possible, for example, to dispense with the plastically or elastically deformable functional layer on the inner tube. In this case, the thermoelectric base elements would be pressed only onto the inner tube.

In a preferred embodiment of the invention, prior to method step D, at least one electrically insulating functional layer is applied between inner tube and thermoelectric base elements and/or between thermoelectric base elements and outer tube. The force fit of the interference fit assembly thus comprises the following components: inner tube, elastic or plastic functional layers, electrically insulating functional layers, thermoelectric base elements and outer tube. These components are thus connected to one another in a partable manner, without cohesive bonds.

The electrically insulating functional layer(s) may be inserted, for example, in the form of tubular films. Another conceivable alternative is coating of the plastically or elastically deformable functional layer with insulating material.

The electrically insulating functional layer results in the advantage that insulation of the thermoelectric base elements can be achieved in a simple manner.

In an alternative embodiment of the invention, an electrically insulating layer is applied to the thermoelectric base elements. This can be effected, for example, in the form of insulation varnish on the connecting bridges of the thermoelectric materials or in the form of an insulating layer over the full area, for example a ceramic layer. The force fit of the interference fit assembly thus comprises the following components: inner tube, elastic or plastic functional layers, thermoelectric base elements and outer tube. These components are thus bonded to one another in a partable manner, without cohesive bonds. The electrically insulating layer, by contrast, is cohesively bonded to the thermoelectric base elements.

In a preferred embodiment, the thermoelectric base elements are insulated by means of a combination of insulating functional layer on one side and insulating coating as part of the base elements on the other side.

In a preferred embodiment of the method of the invention, the interference-fitting force in method step D is matched to a maximum operating temperature of the thermoelectric module. Especially preferably, the interference fit assembly is designed to compensate for or withstand any thermal expansion of the inner tube and/or the outer tube. Since the local heating either of the inner tube or of the outer tube by the hot side can result in occurrence of thermal changes in the dimensions of outer tube and inner tube, typically changes in length or radial expansion, there is the risk that the interference fit assembly will be loosened. This can lead to worsened thermal conductivity or even cause the individual components to slip or fall apart. Advantageously, the interference fit assembly is thus designed for the force fit to be maintained even at a maximum operating temperature.

Typically, temperatures are about 15° C. within the inner tube and in the region of up to 220° C. in the external region outside the outer tube. The thermoelectric semiconductor materials typically used and the solder for the solder bonds of the semiconductor materials with the connecting electrically conductive bridges tolerate maximum operating temperatures in the region of 230° C. It is therefore appropriate to design the interference fit assembly such that the contact pressure tolerates changes in length that can occur at the maximum operating temperatures specified.

However, it is likewise within the scope of the invention to use material groups such as half-Heusler alloys, for example, which can be bonded at far higher temperatures. When these materials are used, the contact pressure in the production of the interference fit assembly is preferably adjusted correspondingly, in order to be able to tolerate the correspondingly higher maximum operating temperatures.

Preference is thus given to bonding inner tube, functional layers, thermoelectric base elements and outer tube without a cohesive bond. “Without a cohesive bond” refers to the essential integrity of the components of the interference fit assembly. This does not rule out solder points for the contact connection of the thermoelectric base elements or for contact connection or the like.

Outer tube and inner tube are preferably designed such that they can be uniformly widened or shrunk, for example in the form of tubes having a circular cross section, rectangular tubes or polygonal tubes or oval tubes, preferably in an axially symmetric or radially symmetric manner.

The inner tube, in a particular embodiment, prior to the interference fitting, may consist of two or more materials that form a solid-based material composite (e.g. intermetallic phase or alloy) from two or more materials as a result of the interference fitting and/or heating. Advantageous properties of said material composite include higher thermal stability, mechanical strength, adjusted thermal expansion, better heat transfer, higher corrosion resistance. Prior to interference fitting, the materials may take various forms: as well as flat and corrugated pipe forms, the materials may also occur as rolled-up films, perforated sheets, meshes or (open-pore) metal foams. It is also possible to use a spiral-shaped bar.

In a preferred embodiment of the invention, in method step C, a multitude of thermoelectric base elements is mounted uniformly over the circumference of the inner tube, preferably symmetrically. These thermoelectric base elements are preferably mounted symmetrically over the circumference of the inner tube. Especially preferably, 12 to 18 thermoelectric base elements are mounted uniformly along the circumference of the inner tube. This results in uniform coverage of the outer surface of the inner tube with thermoelectric base elements, such that uniform heat transfer is possible.

The thermoelectric materials are typically executed as cubes, cuboids, prisms or cylinders with equally large surfaces for the heat source and heat sink. In a specific embodiment, these may also be executed as conical cylinders or conical cuboids in order to achieve the best possible power output. In addition, it is advantageous when the geometries of the two different thermoelectric materials are matched to one another in accordance with their thermoelectric properties so as to maximize efficiency and electrical power output. Details are known from the prior art; see Thermoelectric Devices: Influence of the Legs Geometry and Parasitic Contact Resistances on ZT, Angel Fabian-Mijangos and Jaime Alvarez-Quintana, 2018, DOI: 10.5772/intechopen.75790).

The thermoelectric base elements are preferably electrically connected to one another. However, it is also possible that every thermoelectric base element is tapped individually. However, this is a distinctly more complex implementation. Especially preferably, the thermoelectric base elements are electrically connected to one another in a zigzag arrangement or in a meandering manner. For this purpose, thermoelectric base elements that are adjacent over the circumference are preferably electrically connected such that the base elements are connected in series in accordance with their thermoelectric effect, meaning that, in the case of two adjacent strips, the current preferably flows in opposite directions.

The interstices between the thermoelectric base elements are filled with air in the simplest case. The air achieves thermal insulation in a simple and inexpensive manner. Alternatively, it is also possible, for example, to fill the interstices with foam for poor heat transfer from the hot side to the cold side, or largely to evacuate them, such that vacuum results in poor heat transfer.

In a preferred embodiment of the invention, the functional layer is in multilayer form, preferably at least two-layer form, meaning that a multitude of functional layers is applied by applying at least a first electrically insulating functional layer and a second plastically and/or elastically deformable functional layer between inner tube and thermoelectric base elements. These functional layers may be formed separately or as a layer composite and may also include further interlayers. It is likewise possible for at least a third electrically insulating functional layer and a fourth plastically or elastically deformable functional layer to be applied between thermoelectric base elements and outer tube. The electrically insulating functional layer is disposed on the side of the thermoelectric base elements, since these could otherwise form electrical short circuits via the plastically and/or elastically deformable functional layer. This results in the advantage that the properties of the functional layers can be controlled and good heat transfer can be achieved, especially for the entire layer structure.

In a preferred embodiment, the functional layer may be a coating, a film, or the like, but also the surface of a component, for example the surface of a pipe. If, for example, the inner tube is already formed from a plastic or coated with an electrically insulating material that can be elastically or plastically deformed, it is possible to dispense with any explicit separate functional layer having these features. If the thermoelectric base elements in that case are of such a kind that they couple to the inner tube with low thermal contact resistance, it is possible here to dispense with any functional layer.

The electrically insulating functional layer is preferably formed from polyimide, preferably as a Kapton® film. The plastically or elastically deformable functional layer preferably takes the form of a graphite film. Alternatively, electrically insulating layers used, even for the hot side depending on the thermal property, may be conventional known polymer films, insulating protective varnishes, coatings from coating systems, e.g. SiO₂, parylenes, ceramics or insulating coatings, such as eloxed aluminum tubes, enameled steel tubes or copper with multiple paint layers.

Examples of plastic or elastically deformable functional layers are metal foams, graphite-filled silicones or acrylic polymers filled with thermally conductive ceramic powder.

Many electrically insulating functional layers have poor thermal conductivity. The electrically insulating functional layers should therefore be very thin. Polyimide films in particular are electrically insulating, but have poor thermal conductivity. This film should therefore be very thin. Graphite films are elastically deformable and have good thermal conductivity.

In a preferred embodiment of the process of the invention, the thermoelectric base elements are contact-connected. The thermoelectric base elements are preferably electrically connected to one another, and a common contact connection for the electrically connected thermoelectric base elements is applied. The contact connection is preferably effected only after method step D.

The widening of the inner tube or shrinkage of the outer tube can be effected by mechanical, hydraulic and/or pneumatic forces and/or electromagnetic forming. Alternatively or additionally, it is also possible to achieve a corresponding force by thermal means, for example by a shrinkage sleeve.

In a preferred embodiment of the invention, first of all, the outer tube is provided in a first method step B. Subsequently, the functional layer(s) are applied to the inside of the outer tube in method step C0. Preferably, the functional layers are inserted in the form of tubular films.

Thereafter, the thermoelectric base elements are inserted in method step C, preferably in the form of multiple strips. In a next method step A, the inner tube is inserted and widened in method step D, or the outer tube is shrunk. The inner tube has preferably likewise been provided with a functional layer or functional layers. Alternatively, functional layers in the form of tubular films are likewise inserted between thermoelectric base elements and inner tube.

The object of the invention is likewise achieved by a thermoelectric module having at least an inner tube and an outer tube and at least two thermoelectric base elements.

Essential features are that the thermoelectric base elements have a longitudinal extent parallel to the longitudinal extent of the inner tube and the thermoelectric module has at least one plastically and/or elastically formable functional layer between inner tube and thermoelectric base elements and/or between thermoelectric base elements and outer tube. Moreover, inner tube, functional layers, thermoelectric base elements and outer tube are connected by means of an interference fit assembly.

This results in the advantage that changes in length in particular along the longitudinal extent of the thermoelectric base elements, typically as a result of shear forces on account of changes in length through thermal expansion of the inner tube or the outer tube, are absorbed by the functional layer(s). The plastically or elastically deformable functional layers have flow properties, such that the shear forces resulting from the change in length have a comparatively distinctly smaller adverse effect, if any, on the interference fit assembly.

The thermoelectric module of the invention likewise has the above-described advantages of the method of the invention and preferably has the above-described features of the method of the invention. The thermoelectric module has preferably been produced by the method of the invention.

In a preferred embodiment of the invention, the thermoelectric module has at least one electrically insulating functional layer between inner tube and thermoelectric base elements and/or between thermoelectric base elements and outer tube. The force fit of the interference fit assembly thus comprises the following components: inner tube, elastic or plastic functional layers, electrically insulating functional layers, thermoelectric base elements and outer tube. These components are thus bonded to one another in a partable manner without cohesive bonds.

The electrically insulating functional layer(s) may take the form, for example, of films. Alternatively, coating with insulating material is also possible on the plastically or elastically deformable functional layer.

The electrically insulating functional layer results in the advantage that insulation of the thermoelectric base elements can be achieved in a simple manner.

In an alternative embodiment of the invention, the thermoelectric base materials have at least one electrically insulating layer. This electrically insulating layer may take the form, for example, of insulation varnish on the connecting bridges of the thermoelectric materials or the form of a full-area insulating layer, for example a ceramic layer. The force fit of the interference fit assembly thus comprises the following components: inner tube, elastic or plastic functional layers, thermoelectric base elements and outer tube. These components are thus bonded to one another in a partable manner without cohesive bonds. The electrically insulating functional layer, by contrast, is cohesively bonded to the thermoelectric base elements.

The functional layers are preferably in at least two-layer form, preferably in the form of an electrically insulating functional layer and a plastically and/or elastically deformable functional layer. Possible materials for the electrically insulating functional layer are polyimides, for example Kapton® films. Possible materials for the plastically or elastically deformable functional layer are graphite films.

As already described for the method of the invention, the electrically insulating functional layers are preferably conventional known polymer films, insulating protective lacquers, coatings from coating systems, e.g. SiO₂, parylenes, ceramics or insulating coatings, such as eloxed aluminum tubes, enameled steel tubes or copper with multiple paint layers.

Examples of plastically or elastically deformable functional layers are metal foams, graphite-filled silicones or acrylic polymers filled with thermally conductive ceramic powder.

The electrically insulating functional layer is preferably formed from polyimide, preferably as a Kapton® film. The plastically and/or elastically deformable functional layer preferably takes the form of a graphite film.

In order to prevent the components from falling apart in the event of excess heating of the thermoelectric module above the maximum operating temperature, it is possible to provide adhesive layers. However, these adhesive layers are not essential for the implementation of the invention. The adhesive layers are preferably disposed on the cold side between thermoelectric base elements and the respective adjoining functional layer. This results in the advantage that the adhesive effect is better and more sustained on the cold side. The structure of the thermal base elements is known from the prior art Thermoelectric Devices: Influence of the Legs Geometry and Parasitic Contact Resistances on ZT, Angel Fabian-Mijangos and Jaime Alvarez-Quintana, 2018, DOI: 10.5772/intechopen.75790.

The thermoelectric base elements are formed from p- and n-doped semiconductor elements that are connected to one another in an electrically conductive manner. Typically, solder bonds are used here.

For maximum uniformity of heat transfer, a multitude of thermoelectric base elements is provided, preferably more than ten thermoelectric base elements, especially preferably 18 thermoelectric base elements. The thermoelectric base elements are mounted uniformly in a radially symmetric manner around the circumference of the inner tube. This results in very uniform and efficient heat transfer.

The interstices between the thermoelectric base elements are preferably filled with air. The interstices may alternatively be filled with protective gas or thermal and electrical insulation, or be evacuated.

In a preferred embodiment of the invention, a turbulator, especially a turbulator in spiral form, a turbulator in screw form or a left/right-twisted (L-R twisted) turbulator, is provided within the inner tube. This results in better heat transfer. In addition, the turbulator leads to improved mechanical stability of the arrangement.

The object of the invention is likewise achieved by a heat exchanger having at least one thermoelectric module, formed according to one of the above-described embodiments. This enables robust, long-lived heat exchanger designs. In particular, there is no change in handling, for example in the cleaning of the heat exchangers compared to the heat exchangers known to date. This means that no additional service and maintenance costs arise as a result of the thermoelectric internals.

It is a particular advantage of the invention that heat flows in such a way that an external hot side is more easily implementable than in the case of many solutions known from the prior art: when the hot side is on the outside, i.e. outside the outer tube, this will generally expand radially to a greater extent than the colder inner tube. This can give rise to very high tension forces, especially in the cohesive solder bonds, which can damage or destroy the bond.

Conversely, compressive forces that occur in the case of more significant expansion of the inner tube by virtue of a hot side in the inner tube are typically less critical.

Since, in accordance with the invention, the forces that arise are absorbed or at least reduced by the functional layer, the invention simplifies or improves the options for implementation of an outer hot side.

In addition, the configuration of the invention prevents overheating of the solder sites on the hot side of the thermoelectric base elements if the heat transferer heats up more quickly on the outside than the internal components, in that the contact pressure in the case of excessively high temperatures onto the outer tube will decrease to such an extent that heat transfer by thermal conduction from the outer tube through the interlayer to the base element becomes poorer. The thermal contact resistance will increase, and the solder site temperature will increase to a declining degree with the hot side temperature. The declining contact pressure thus protects the solder sites from overheating.

The production method of the invention for thermoelectric modules is especially suitable for production of thermoelectric modules and heat exchangers for the conversion of waste heat to power. Possible fields of use are, for example, thermoelectric generators for thermal baths, boilers, ovens, waste heat utilization in ships, locomotives or vehicles having engines. Alternatively, the thermoelectric base elements may be used in the form of Peltier elements for controlling the temperature of fluids, improving cooling and heat pump circuits, or as actuators. The invention does accept that heat transfer to the thermoelectric base elements is reduced compared to the solutions known from the prior art, but profits from distinctly reduced manufacturing costs.

### BRIEF DESCRIPTION OF THE DRAWINGS

Further preferred features and embodiments of the production process of the invention and of the thermoelectric module of the invention are elucidated hereinafter by working examples and the figures. The figures show:

FIGS. 1 and 1A a schematic diagram of a thermoelectric module in a section along the longitudinal extent of the thermoelectric base elements;

FIG. 2 an exploded diagram of a thermoelectric module;

FIG. 3 a schematic diagram of a thermoelectric module in cross section.

### DETAILED DESCRIPTION

Identical reference numerals in the figures denote elements that are the same or have the same effect.

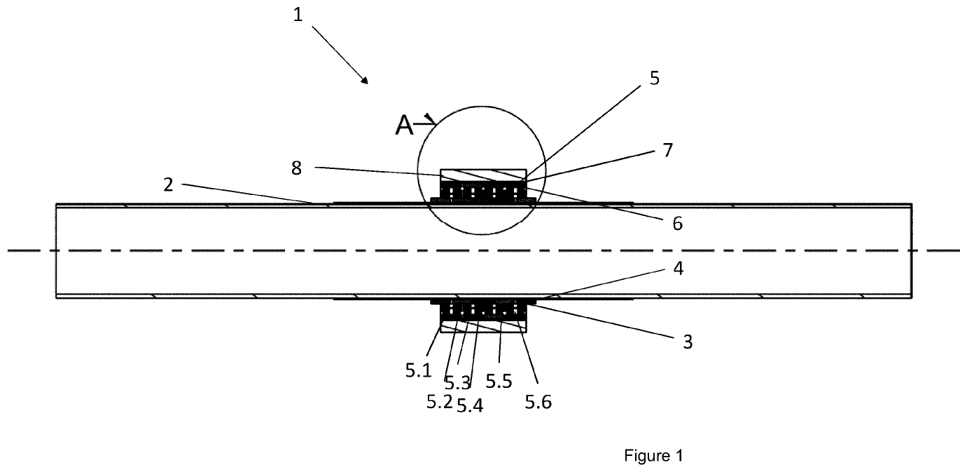

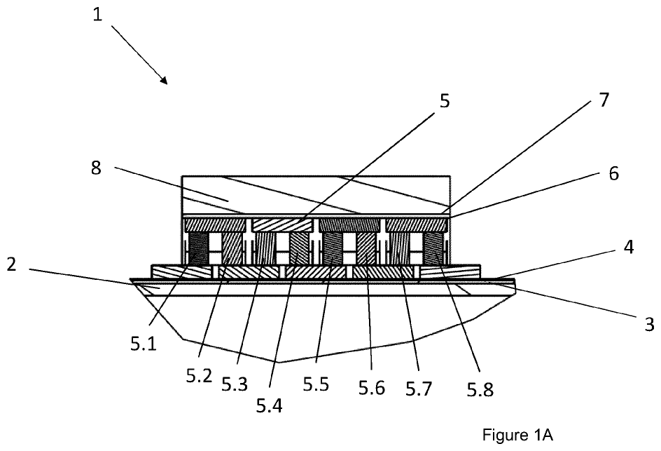

FIG. 1 shows a schematic diagram of a thermoelectric module 1 in longitudinal section with a part-image in FIG. 1A.

The thermoelectric module 1 comprises an inner tube 2 and an outer tube 8. A graphite film 3 has been applied to the inner tube 2. The graphite film 3 has a thickness of 100 to 250 micrometers. A polyimide film 4, in the present context a Kapton® film, has been applied to the graphite film 3. The Kapton® film is very thin and has a thickness in the range of 7-30 micrometers. The thermoelectric base elements 5 have been applied to the Kapton® film with their longitudinal extent parallel to the longitudinal extent of the inner tube 2. In the present case, 18 thermoelectric base elements 5 have been provided.

A second two-layer functional layer, in the present case in the form of a polyimide layer 6, likewise in the present case in the form of a Kapton® film, and a graphite film 7, have been provided atop the thermoelectric base elements 5. The outer tube 8 has been placed on top of the graphite film 7.

The thermoelectric base elements 5 have been formed from thermoelectric semiconductor materials, in the present case BiTe alloys.

The thermoelectric base elements 5 have respectively alternating p- and n-doped semiconductors that are connected to one another in an electrically conductive manner via solder bridges. In the present case, the thermoelectric base elements 5 are formed with six semiconductor elements each: three p-doped semiconductor elements 5.1, 5.3, 5.5 and three n-doped semiconductor elements 5.2, 5.4, 5.6. 18 thermoelectric base elements 5 are applied with equal separation in circumferential direction around the inner tube 2. This assures uniform heat transfer.

The 18 thermoelectric base elements 5 are connected to one another in an electrically conductive manner and have a common contact connection (not shown).

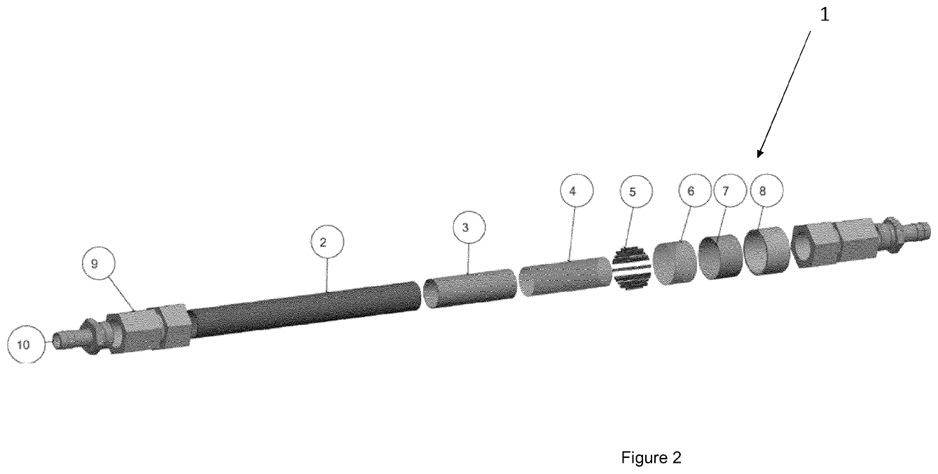

A configuration of the method of the invention is to be described hereinafter with reference to the exploded diagram in FIG. 2:

In a first method step A, the inner tube 2 is provided.

In the subsequent method step C0, the elastically deformable first functional layer, in the present case a graphite film 3, and the second electrically insulating functional layer, a polyimide film 4, in the present case a Kapton® film, are applied to the inner tube 2.

The thermoelectric base elements 5 are mounted onto the polyimide film 4 in method step C. The thermoelectric base elements 5 are applied with their longitudinal extent parallel to the longitudinal extent of the inner tube 2. The thermoelectric base elements 5 here are operatively connected to the functional layers in particular.

The first functional layer and second functional layer are formed so as to cooperate such that there is good thermal conductivity, i.e. good thermal contact, between the thermoelectric base elements and the volume of the inner tube, such that the temperature differential across the functional layer is at a minimum compared to the temperature differential across the thermoelectric base elements.

In a further, a third electrically insulating functional layer and a fourth elastically deformable functional layer, in the present case a Kapton® film 6 and a graphite film 7, are applied to the thermoelectric base elements 5.

In a method step B, the outer tube 8 is provided and pushed over the coated thermoelectric base elements 5. Finally, in a method step D, the shrinkage of the outer tube 8 produces an interference fit assembly composed of inner tube 2, functional layers 3, 4, 6, 7, thermoelectric base elements 5 and outer tube 8.

In the present case, the interference fit assembly is produced by the widening of the inner tube 2. The interference-fitting force here is such that the change in length is compensated for by the interference-fitting force as a result of the thermal expansion of the outer tube in the state of operation.

There is thus advantageously no need to use unreliable cohesive bonds for the bonding of the elements mentioned: inner tube 2, functional layers 3, 4, 6, 7, thermoelectric base elements 5 and outer tube 8. As a result, shear forces on account of different changes in axial length, typically caused by thermal expansion as a result of the differences in temperature of the hot side and cold side of thermoelectric modules, are compensated for by the elastic functional layers 3, 7. By virtue of the elastic properties, the functional layers 3, 7 are able to follow thermal or mechanical influences in that, for example, they show flow characteristics or tolerate elastic deformation. This enables very flexible use of the thermoelectric modules 1 both with an external and an internal hot side.

The method may alternatively be conducted in the reverse sequence. For this purpose, first of all, the outer tube 8 is provided in a first method step. Subsequently, the functional layers are pushed into the outer tube 8 in the form of tubular films 6, 7. Thereafter, the thermoelectric base elements 5 are pushed in, preferably in the form of multiple strips. In a next step, the inner functional layers 3, 4 are pushed in in the form of tubular films on the inside of the thermoelectric base elements 5. Subsequently, the inner tube 2 is pushed in and widened.

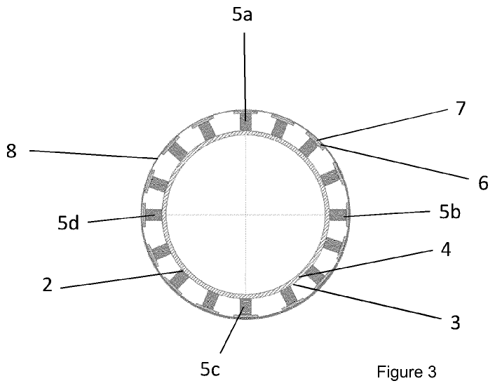

FIG. 3 shows a schematic diagram of a cross section through the thermoelectric module 1.

What are shown are the thermoelectric base elements, identified by way of example by reference numerals 5a, 5b, 5c, 5d, in the present context 12 thermoelectric semiconductor elements disposed in circumferential direction between inner tube 2 and outer tube 8. The two-layer functional layer 3, 4 is shown between inner tube and thermoelectric semiconductor elements 5a, 5b, 5c, 5d. A two-layer functional layer 6, 7 is likewise shown between thermoelectric base elements 5a, 5b, 5c, 5d and outer tube 8.

The two two-layer functional layers in the present context are in the form of a Kapton® film 4, 6 and a graphite film 3, 7. The insulating Kapton® film 4, 6 is disposed in each case on the side facing the thermoelectric base elements 5.

In the state of operation as thermoelectric generator, the inner tube 2 advantageously constitutes the cold side, while the hot side is outside the outer tube 8. However, there is no barrier to operation in the reverse heat flow direction.

1. A method of producing a thermoelectric module (1) from at least an inner tube (2) and an outer tube (8) and at least two thermoelectric base elements (5), the method comprises the following method steps:
A providing the inner tube (2);
B providing the outer tube (8);
C providing the thermoelectric base elements (5) outside the inner tube (2) or inside the outer tube;
D at least one of widening the inner tube (2) or shrinking the outer tube (8); and
in a method step C0 prior to method step D, applying at least one plastically or elastically deformable functional layer (3, 7) at least one of between inner tube (2) and thermoelectric base elements (5) or between thermoelectric base elements (5) and outer tube (8), and arranging the thermoelectric base elements (5) in method step C with a longitudinal extent thereof parallel to a longitudinal extent of the inner tube (2) and operatively connected to the functional layer, such that the at least one of the widening of the inner tube (2) or shrinking of the outer tube (8) forms an interference fit assembly comprised of the inner tube (2), the at least one functional layer (3, 7), the thermoelectric base elements (5) and the outer tube (8).

2. The method as claimed in claim 1, further comprising prior to method step D, applying at least one electrically insulating functional layer (4, 6) at least one of between the inner tube (2) and the thermoelectric base elements (5) or the thermoelectric base elements (5) and the outer tube (8).

3. The method as claimed in claim 1, further comprising applying an electrically insulating layer to the thermoelectric base elements (5).

4. The method as claimed in claim 1, wherein the interference-fitting force in method step D is matched to a maximum operating temperature of the thermoelectric module (1) to compensate for any thermal expansion of at least one of the inner tube (2) or the outer tube (8).

5. The method as claimed in claim 1, wherein the inner tube (2), the functional layers, the thermoelectric base elements (5) and the outer tube (8) are connected without a cohesive bond.

6. The method as claimed in claim 1, wherein, in method step C, a multitude of said thermoelectric base elements (5) are mounted uniformly over a circumference of the inner tube (2).

7. The method as claimed in claim 1, wherein a multitude of functional layers are applied, including at least one of a first plastically or elastically deformable functional layer (3) and a second electrically insulating functional layer (4) between the inner tube (2) and the thermoelectric base elements (5), or a first electrically insulating functional layer (6) and a second plastically or elastically deformable functional layer (7) between the thermoelectric base elements (5) and the outer tube (8).

8. The method as claimed in claim 1, wherein the thermoelectric base elements (5) are electrically connected to one another and a common contact connection is applied for the electrically connected thermoelectric base elements.

9. A thermoelectric module (1) comprising:
at least an inner tube (2);
an outer tube (8);
at least two thermoelectric base elements (5);
the thermoelectric base elements (5) have a longitudinal extent parallel to a longitudinal extent of the inner tube (2);
at least one plastically and/or elastically deformable functional layer (3, 7) between at least one of the inner tube (2) and the thermoelectric base elements (5) or the thermoelectric base elements (5) and the outer tube (8); and
the inner tube (2), the at least one functional layer (3, 7), the thermoelectric base elements (5) and the outer tube (8) are connected by an interference fit assembly.

10. The thermoelectric module (1) as claimed in claim 9, further comprising at least one electrically insulating functional layer (4, 6) between at least one of the inner tube (2) and the thermoelectric base elements (5) or the thermoelectric base elements (5) and the outer tube (8).

11. The thermoelectric module (1) as claimed in claim 9, wherein the thermoelectric base elements (5) have at least one electrically insulating layer.

12. The thermoelectric module (1) as claimed in claim 9, wherein the functional layer comprises at least two layers, including an electrically insulating functional layer (4, 6) and a plastically or elastically deformable functional layer (3, 7).

13. The thermoelectric module (1) as claimed in claim 9, further comprising at least one of a first electrically insulating functional layer (4, 6) and a second plastically or elastically deformable functional layer (3, 7) between the inner tube (2) and the thermoelectric base elements (5) or a first electrically insulating functional layer (4, 6) and a second plastically or elastically deformable functional layer (3, 7) between the thermoelectric base elements (5) and the outer tube (8).

14. The thermoelectric module (1) as claimed in claim 9, further comprising at least one adhesive layer disposed on a cold side between the thermoelectric base elements (5) and an adjoining one of the at least one functional layer.

15. The thermoelectric module (1) as claimed in claim 9, wherein the thermoelectric base elements (5) are formed from p- and n-doped semiconductor elements that are connected to one another in an electrically conductive manner.

16. The thermoelectric module (1) as claimed in claim 9, wherein there are a multitude of said thermoelectric base elements (5) that are mounted uniformly, in a radially symmetric manner along a circumference of the inner tube (2).

17. The thermoelectric module as claimed in claim 9, further comprising a turbulator in the inner tube (2).

18. The thermoelectric module as claimed in claim 9, wherein at least one of the inner tube (2) or the outer tube (8) is formed from a shape-memory alloy.

19. A heat exchanger comprising:
at least one said thermoelectric module (1) according to claim 9;
a housing; and
a fluid feed on a hot side and a fluid feed on a cold side.

20. A thermoelectric generator comprising: at least one heat exchanger having at least one said thermoelectric module (1) as claimed in claim 9.

21. A cooling device comprising: at least one heat exchanger having at least one said thermoelectric module (1) as claimed in claim 9.

22. (canceled)
